(19) United States
(12) Patent Application Publication
(10) Pub. No.: US 2020/0136070 A1
(43) Pub. Date: Apr. 30, 2020

(54) ORGANIC SEMICONDUCTOR THIN FILM, AND THIN FILM TRANSISTOR AND ELECTRONIC DEVICE INCLUDING THE SAME

(71) Applicants: Samsung Electronics Co., Ltd., Suwon-si (KR); THE BOARD OF TRUSTEES OF THE LELAND STANFORD JUNIOR UNIVERSITY, Stanford, CA (US)

(72) Inventors: Youngjun YUN, Yongin-si (KR); Zhenan Bao, Stanford, CA (US); Jie Xu, Stanford, CA (US)

(73) Assignees: Samsung Electronics Co., Ltd., Suwon-si (KR); THE BOARD OF TRUSTEES OF THE LELAND STANFORD JUNIOR UNIVERSITY, Stanford, CA (US)

(21) Appl. No.: 16/669,957

(22) Filed: Oct. 31, 2019

Related U.S. Application Data
(60) Provisional application No. 62/753,248, filed on Oct. 31, 2018.

(51) Int. Cl. H01L 51/00

(52) U.S. Cl. CPC H01L 51/0097; H01L 51/0043; H01L 2251/5338; H01L 51/0074; H01L 51/0072

(57) ABSTRACT

A stretchable organic semiconductor thin film including a network of conjugated semiconductor polymers including at least one conjugated structural unit and a plasticizer compound dispersed in the polymer network and having a linear or branched aliphatic hydrocarbon group, wherein the conjugated structural unit includes at least one long-chain linear or branched aliphatic hydrocarbon group at the side chain.

### CROSS-REFERENCE TO RELATED APPLICATION

This application claims priority to and the benefit of U.S. Provisional Patent Application No. 62/753,248, filed in the United States Patent and Trademark Office on Oct. 31, 2018, the entire content of which is incorporated herein by reference.

### BACKGROUND

### 1. Field

An organic semiconductor thin film and a thin film transistor and an electronic device including the same are disclosed.

### 2. Description of the Related Art

The recent development of portable and smart electronics has changed the way humans interact and communicate with electronic devices. As a result of these changes, devices and components made from only traditionally rigid electronic materials are no longer sufficient. For example, stress-strain sensors, artificial muscles, and wearable devices are some examples of devices which could benefit from components resistant to inelastic deterioration or fracturing.

As a result, elastic electronic materials (e.g., polymer semiconductor materials) that are able to be stretched and are able to endure various motions have attracted increasing attention.

The stretchable electronic device may include a thin film transistor (TFT) as a basic element, and an organic semiconductor thin film may be a part of the stretchable thin film transistor.

Accordingly, plenty of research on providing an organic semiconductor thin film with improved stretchability has been made. However, currently developed technologies have a problem that a polymer film may deteriorate under large or repeated strain, or that the electrical characteristics may be deteriorated.

### SUMMARY

An embodiment provides an organic semiconductor thin film that may exhibit electrical characteristics and stretchability simultaneously.

Another embodiment provides a thin film transistor including the organic semiconductor thin film.

Yet another embodiment provides an electronic device including the organic semiconductor thin film or the thin film transistor.

According to an embodiment, a stretchable organic semiconductor thin film includes a network of conjugated semiconductor polymers including at least one conjugated structural unit and a plasticizer compound dispersed in the polymer network and having a linear or branched aliphatic hydrocarbon group, wherein the conjugated structural unit includes at least one long-chain linear or branched aliphatic hydrocarbon group as a side chain.

The long-chain linear or branched aliphatic hydrocarbon group may be a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group.

The conjugated structural unit may include at least one of a moiety represented by Chemical Formulae 1-1 to 1-7.

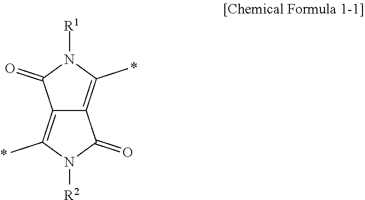

In Chemical Formula 1-1,

R¹ and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R¹ and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

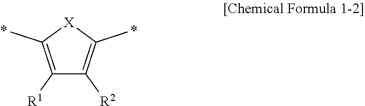

In Chemical Formula 1-2,

X is O, S, Se, or NR^{a}, wherein R^{a}, R¹, and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided at least one of R^{a}, R¹, and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

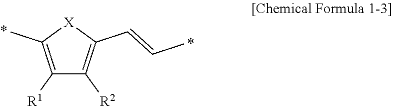

In Chemical Formula 1-3,

X is O, S, Se, or NR^{a}, wherein R^{a}, R¹, and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R^{a}, R¹, and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

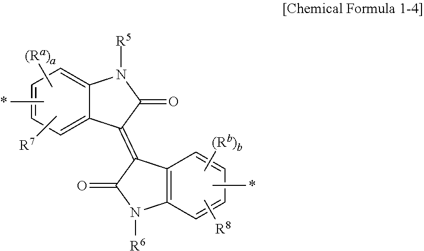

In Chemical Formula 1-4,

R⁵, R⁶, R⁷, and R⁸ are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R⁵, R⁶, R⁷, and R⁸ is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, R^{a} and R^{b} are a C1 to C6 alkyl group, a and b are independently an integer of 0 to 2, and * is a linking portion with an adjacent moiety.

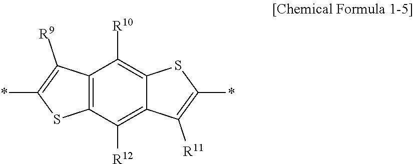

In Chemical Formula 1-5,

R⁹, R¹⁰, R¹¹, and R¹² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R⁹, R¹⁰, R¹¹ and R¹² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

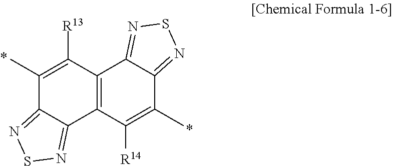

In Chemical Formula 1-6,

R¹³ and R¹⁴ are independently hydrogen, a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, provided that at least one of R¹³ and R¹⁴ is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

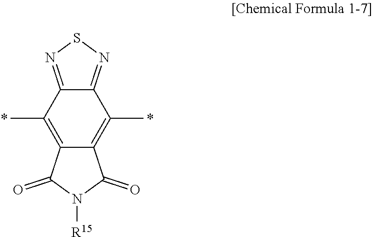

In Chemical Formula 1-7,

R¹⁵ is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

The conjugated structural unit may further include at least one of a moiety represented by Chemical Formulae 2-1 to 2-7.

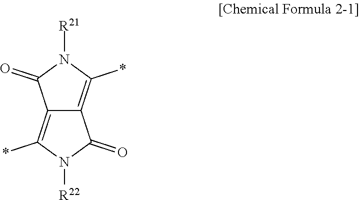

In Chemical Formula 2-1,

R²¹ and R²² are independently hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety.

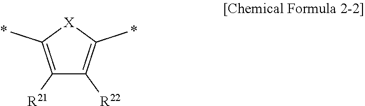

In Chemical Formula 2-2,

X is O, S, Se, or NR^{a} (wherein R^{a} is hydrogen or a C1 to C6 alkyl group), R²¹ and R²² are independently hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety.

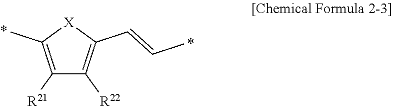

In Chemical Formula 2-3,

X is O, S, Se, or NR^{a} (wherein R^{a} is hydrogen or a C1 to C6 alkyl group), R²¹ and R²² is hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety.

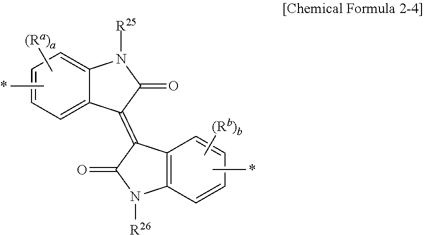

In Chemical Formula 2-4,

R²⁵ and R²⁶ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, R^{a} and R^{b} are a C1 to C6 alkyl group, a and b are independently an integer of 0 to 3, and * is a linking portion with an adjacent moiety.

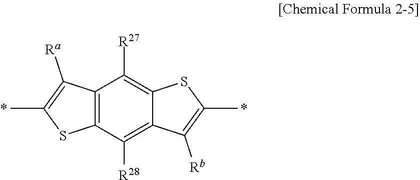

In Chemical Formula 2-5,

R²⁷ and R²⁸ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, R^{a} and R^{b} is hydrogen or a C1 to C6 alkyl group, and * is a linking portion with an adjacent moiety.

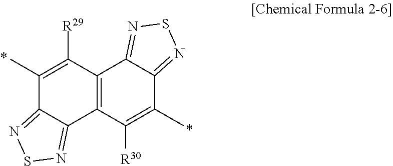

In Chemical Formula 2-6,

R²⁹ and R³⁰ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety.

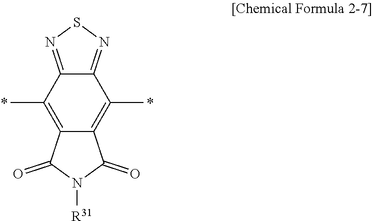

In Chemical Formula 2-7,

R³¹ is hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety.

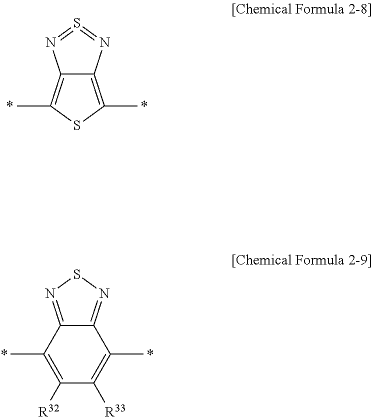

In Chemical Formula 2-9,

R³² and R³³ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety.

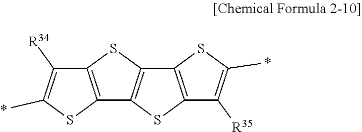

In Chemical Formula 2-10,

R³⁴ and R³⁵ are independently hydrogen, a halogen (F—, Cl—, Br—, or I—), a substituted or unsubstituted C1 to C40 alkyl group, a substituted or unsubstituted C2 to C40 alkenyl group, a substituted or unsubstituted C2 to C40 alkynyl group or a substituted or unsubstituted C6 to C30 aryl group, and * is a linking portion with an adjacent moiety.

The conjugated semiconductor polymer may for example further include a substituted or unsubstituted phenylene, a substituted or unsubstituted thiazole, a substituted or unsubstituted pyridine, a substituted or unsubstituted bipyridine, a substituted or unsubstituted naphthalene, a substituted or unsubstituted anthracene, a substituted or unsubstituted phenanthroline, a substituted or unsubstituted naphthacene, a substituted or unsubstituted fluorene, a substituted or unsubstituted carbazole, a substituted or unsubstituted thienothiophene, a substituted or unsubstituted thieno benzothiophene, or a combination thereof, in addition to the structural units represented by Chemical Formulae 1-1 to 1-7 and optionally the structural units represented by Chemical Formulae 2-1 to 2-10.

The conjugated semiconductor polymer may include a structural unit represented by Chemical Formula 3.

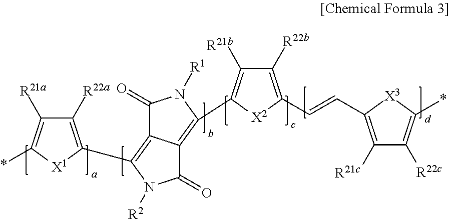

In Chemical Formula 3,

R¹ and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R¹ and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group,

X¹, X², and X³ are the same or different and are independently O, S, Se, or NR^{a} (wherein R^{a} is hydrogen or a C1 to C6 alkyl group),

R^{21a}, R^{22a}, R^{21b}, R^{22b}, R^{21c}, and R^{22c} are the same or different and are independently hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group,

* is a linking portion with an adjacent moiety,

a, c, and d are independently 0 to 10, and

b is 1 to 10.

The linear or branched aliphatic hydrocarbon group of the plasticizer compound having the linear or branched aliphatic hydrocarbon group may be a substituted or unsubstituted C6 to C50 linear or branched alkyl group, a substituted or unsubstituted C6 to C50 linear or branched alkoxy group, a substituted or unsubstituted C6 to C50 linear or branched alkenyl group, or a substituted or unsubstituted C6 to C50 linear or branched alkynyl group.

The plasticizer compound having the linear or branched aliphatic hydrocarbon group may be an aromatic or aliphatic compound having an ester group-containing linear or branched aliphatic hydrocarbon group. The aromatic or aliphatic compound having the ester group-containing linear or branched aliphatic hydrocarbon group may be a phthalate-based compound, a trimellitate-based compound, an aliphatic ester-based compound, or a combination thereof.

The plasticizer compound having the linear or branched aliphatic hydrocarbon group may be dibutyl phthalate (DBP), dioctyl phthalate (DOP), diisononyl phthalate (DINP), di-isodecyl phthalate (DIDP), dihexyl phthalate (DEHP), diheptyl phthalate, diisodecyl phthalate, diundecyl phthalate, di-isooctylphthalate (DIOP), di-capryl phthalate (DCP), di-n-octylphthalate (DOP), di-2-ethylhexyl isophthalate (DOIP), di-2-ethylhexyl terephthalate (DOTP), di-isononyl phthalate (DIHP), di-n-C6,C8,C10 phthalate (NHDP), di-linear-C7,C9,C11 phthalate (NHUP), di-tridecyl phthalate (DTDP), di-iso-C11,C12,C13 phthalate (UDP), di-linear-C11 phthalate (DUP), trioctyl trimellitate (TOTM), tri-i-tridecyl trimellitate, triisononyltrimellitate (TINTM), a maleate compound such as dioctyl maleate; an adipate compound such as dibutyl adipate (DBA) or dioctyl adipate; dioctyl sebacate (DOS), dioctyl azelate (DOZ), or a combination thereof.

The plasticizer compound having the linear or branched aliphatic hydrocarbon group may have a molecular weight of greater than or equal to about 250 g/mol. The plasticizer compound having the linear or branched aliphatic hydrocarbon group may have a boiling point of greater than or equal to about 350° C.

The plasticizer compound having the linear or branched aliphatic hydrocarbon group may be included in an amount of about 0.1 parts by weight to about 2 parts by weight based on 1 part by weight of the conjugated semiconductor polymer.

According to another embodiment, a thin film transistor includes the organic semiconductor thin film.

The thin film transistor may include a gate electrode, an insulation layer disposed on the gate electrode, a semiconductor layer including the organic semiconductor thin film and disposed on the insulation layer, and a source electrode and a drain electrode electrically connected to the semiconductor layer.

According to another embodiment, an electronic device includes the organic semiconductor thin film.

The organic semiconductor thin film improves stretchability as well as maintains improved electrical characteristics and thus may be usefully applied to an electronic device requiring high stretchability and self-healing properties.

### BRIEF DESCRIPTION OF THE DRAWINGS

FIG. 1A is a schematic cross-sectional view showing a thin film transistor according to an embodiment.

FIG. 1B is a schematic cross-sectional view showing a thin film transistor according to an embodiment without strain (upper) and with strain (bottom).

FIG. 2 is a schematic cross-sectional view showing the structure of an electrocardiogram (ECG) sensor.

FIG. 3 is a graph showing a π-π stacking distance of organic semiconductor thin film according to Comparative Example 1 and Examples 1 and 4.

FIG. 4 is a graph showing the laminar stacking distance of the organic semiconductor thin films according to Comparative Example 1 and Examples 1 and 4.

FIGS. 5A and 5B are polarized microscopic photographs respectively showing the organic semiconductor thin films according to Example 2 (100%) and Comparative Example 1 (100%).

FIG. 6 is a graph showing mobility of the thin film transistors according to Comparative Examples 2 (100%), 7 (100%), 8 (100%), and 9 (100%).

FIG. 7 is a graph showing drain current (on current, gray line) and gate leakage current (off current, black line) measurement results of the thin film transistor according to Example 8 under a turn-on state (VG=−100 V, VD=−100 V).

FIG. 8 is a graph showing a drain current (on current, gray line) and gate leakage current (off current, black line) measurement result of the thin film transistor according to Example 11 under a turn-on state (VG=−100 V, VD=−100 V).

FIG. 9 is a graph showing transfer (VGS sweep) characteristics of the thin film transistors according to Comparative Example 2 and Example 11.

### DETAILED DESCRIPTION

The embodiments provided should not be construed as being limited to the embodiments set forth herein. If not defined otherwise, all terms (including technical and scientific terms) in the specification may be defined as commonly understood by one skilled in the art. The terms defined in a generally-used dictionary may not be interpreted ideally or exaggeratedly unless clearly defined. The terms defined in a generally-used dictionary may be interpreted to have meaning in this related art and in the present disclosure, and may not be interpreted ideally or exaggeratedly unless clearly defined.

Further, the singular includes the plural unless mentioned otherwise.

In the drawings, the thickness of layers, films, panels, regions, etc., are exaggerated for clarity. Like reference numerals designate like elements throughout the specification.

It will be understood by a person having ordinary skilled in the art that when an element such as a layer, film, region, or substrate is referred to as being “on” another element, it can be directly on the other element or intervening elements may also be present. In contrast, when an element is referred to as being “directly on” another element, there are no intervening elements present.

As used herein, when a definition is not otherwise provided, “substituted” refers to replacement of hydrogen of a compound or a functional group by a substituent selected from a halogen atom, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, sulfonic acid group or a salt thereof, a phosphoric acid group or a salt thereof, a C1 to C20 alkyl group, a C1 to C20 alkoxy group, a C1 to C20 haloalkyl group, a C2 to C20 alkenyl group, a C2 to C20 alkynyl group, a C6 to C30 aryl group, a C7 to C30 arylalkyl group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, when a definition is not otherwise provided, “hetero” refers to inclusion of at least one, for example 1 to 3 heteroatoms selected from N, O, S, Si, Se, and P in a group or a compound.

As used herein, “conjugated structural unit” refers to a p orbital structural unit (e.g., moiety) having delocalized electrons and connected to other in molecules having alternating single and multiple (e.g., double) bonds. The conjugated structural unit decreases the overall energy in a molecule and improves stability. The moiety may be a cyclic, acyclic, linear, or a mixed type.

As used herein, “combination” refers to a mixture of two or more, a stack structure of two or more, or mutual substitution.

An organic semiconductor thin film according to an embodiment includes a network of conjugated semiconductor polymers including at least one conjugated structural unit and a plasticizer compound dispersed in the polymer network and having a linear or branched aliphatic hydrocarbon group, wherein the conjugated structural unit includes at least one long-chain linear or branched aliphatic hydrocarbon group at the side chain. The organic semiconductor thin film may be elastically stretchable.

The conjugated semiconductor polymer may include any semiconductor polymer having a conjugated structural unit including at least one long-chain linear or branched aliphatic hydrocarbon group at the side chain without a particular limit, for example, a donor-acceptor type polymer having both of an electron donating moiety and an electron accepting moiety. The conjugated semiconductor polymer includes plenty of delocalized electrons in the main chain and thus may have improved charge carrier transport capability.

At least one long-chain linear or branched aliphatic hydrocarbon group at the side chain of the conjugated semiconductor polymer may increase π-π stacking of the conjugated semiconductor polymers.

The long-chain linear or branched aliphatic hydrocarbon group may be a C10 to C50 linear or branched aliphatic hydrocarbon group, for example a C15 to C50 linear or branched aliphatic hydrocarbon group or a C20 to C50 linear or branched aliphatic hydrocarbon group.

The long-chain linear or branched aliphatic hydrocarbon group may be a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, a substituted or unsubstituted C15 to C50 linear or branched alkenyl group or a substituted or unsubstituted C20 to C50 linear or branched alkenyl group, and a substituted or unsubstituted C10 to C50 linear or branched alkynyl group, for example a substituted or unsubstituted C15 to C50 linear or branched alkynyl group, or a substituted or unsubstituted C20 to C50 linear or branched alkynyl group. For the long-chain linear or branched aliphatic hydrocarbon group, “substituted” may refer to replacement of hydrogen of a functional group by a functional group selected from a halogen atom, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C20 alkyl group, a C1 to C20 alkoxy group, a C1 to C20 haloalkyl group, a C2 to C20 alkenyl group, a C2 to C20 alkynyl group, and a C1 to C20 heteroalkyl group.

The conjugated structural unit may include at least one of a moiety represented by Chemical Formulae 1-1 to 1-7.

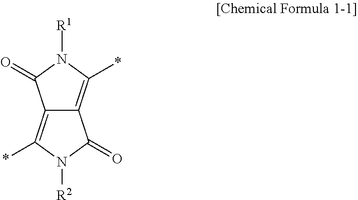

In Chemical Formula 1-1,

R¹ and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R¹ and R² is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, and * is a linking portion with an adjacent moiety.

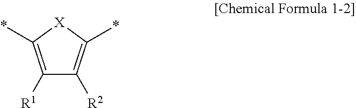

In Chemical Formula 1-2,

X is O, S, Se, or NR^{a}, wherein R^{a}, R¹, and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided at least one of R^{a}, R¹, and R² is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, and * is a linking portion with an adjacent moiety.

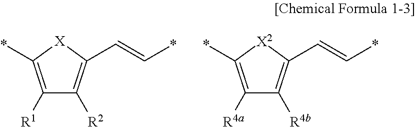

In Chemical Formula 1-3,

X is O, S, Se, or NR^{a}, wherein R^{a}, R¹, and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R^{a}, R¹, and R² is a substituted or unsubstituted substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, and * is a linking portion with an adjacent moiety.

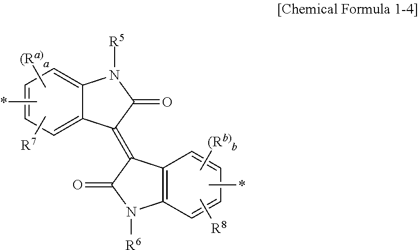

In Chemical Formula 1-4,

R⁵, R⁶, R⁷, and R⁸ are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R⁵, R⁶, R⁷, and R⁸ is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, R^{a} and R^{b} are a C1 to C6 alkyl group, a and b are independently an integer of 0 to 2, and * is a linking portion with an adjacent moiety.

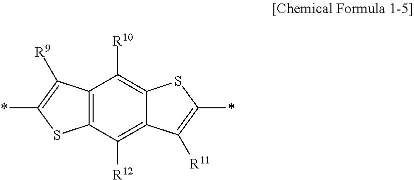

In Chemical Formula 1-5,

R⁹, R¹⁰, R¹¹, and R¹² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R⁹, R¹⁰, R¹¹, and R¹² is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, R^{a} and R^{b} is hydrogen or a C1 to C6 alkyl group, and * is a linking portion with an adjacent moiety.

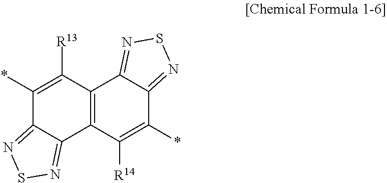

In Chemical Formula 1-6,

R¹³ and R¹⁴ are independently hydrogen, a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, provided that at least one of R¹³ and R¹⁴ is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, and * is a linking portion with an adjacent moiety.

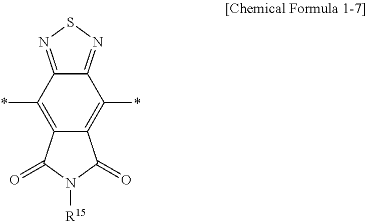

In Chemical Formula 1-7,

R¹⁵ is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group, and * is a linking portion with an adjacent moiety.

The conjugated structural unit may further include at least one of a moiety represented by Chemical Formulae 2-1 to 2-7.

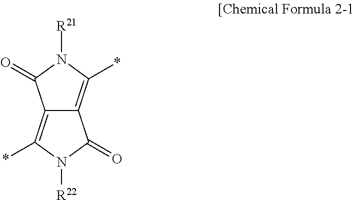

In Chemical Formula 2-1,

R²¹ and R²² are independently hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety.

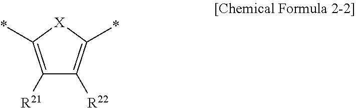

In Chemical Formula 2-2,

X is O, S, Se, or NR^{a} (wherein R^{a} is hydrogen or a C1 to C6 alkyl group), R²¹ and R²² is hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety.

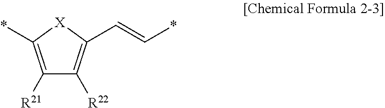

In Chemical Formula 2-3,

X is O, S, Se, or NR^{a} (wherein R^{a} is hydrogen or a C1 to C6 alkyl group), R²¹ and R²² is hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety.

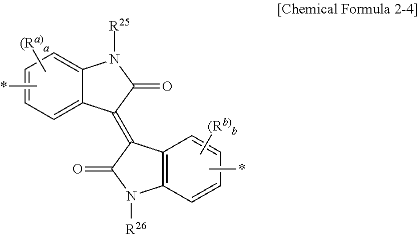

In Chemical Formula 2-4,

R²⁵ and R²⁶ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, R^{a} and R^{b} are a C1 to C6 alkyl group, a and b are independently an integer of 0 to 3, and * is a linking portion with an adjacent moiety.

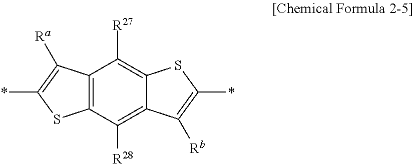

In Chemical Formula 2-5,

R²⁷ and R²⁸ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, R^{a} and R^{b} is hydrogen or a C1 to C6 alkyl group, and * is a linking portion with an adjacent moiety.

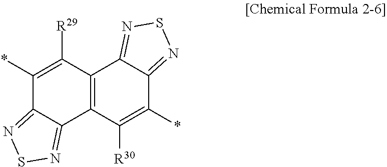

In Chemical Formula 2-6,

R²⁹ and R³⁹ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety.

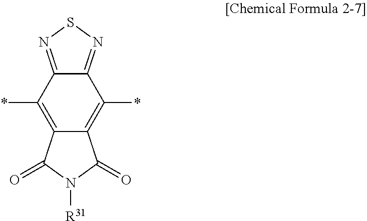

In Chemical Formula 2-7,

R³¹ is hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety.

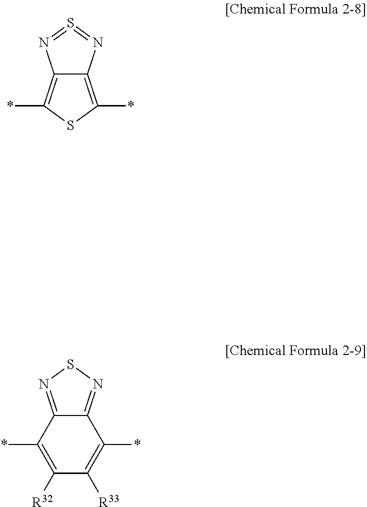

In Chemical Formula 2-9,

R³² and R³³ are independently hydrogen, a halogen (F—, Cl—, Br—, or I—), a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety.

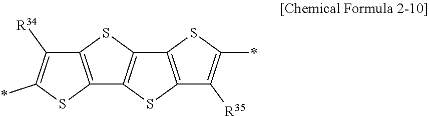

In Chemical Formula 2-10,

R³⁴ and R³⁵ are independently hydrogen, a halogen (F—, Cl—, Br—, or I—), a substituted or unsubstituted C1 to C40 alkyl group, a substituted or unsubstituted C2 to C40 alkenyl group, a substituted or unsubstituted C2 to C40 alkynyl group, or a substituted or unsubstituted C6 to C30 aryl group, and * is a linking portion with an adjacent moiety.

The conjugated semiconductor polymer may for example further include a substituted or unsubstituted phenylene, a substituted or unsubstituted thiazole, a substituted or unsubstituted pyridine, a substituted or unsubstituted bipyridine, a substituted or unsubstituted naphthalene, a substituted or unsubstituted anthracene, a substituted or unsubstituted phenanthroline, a substituted or unsubstituted naphthacene or substituted or unsubstituted fluorene, a substituted or unsubstituted carbazole, a substituted or unsubstituted thienothiophene, a substituted or unsubstituted thieno benzothiophene, or a combination thereof in addition to the structural units represented by Chemical Formulae 1-1 to 1-7 and optionally the structural units represented by Chemical Formulae 2-1 to 2-10, but is not limited thereto.

The conjugated semiconductor polymer may have a weight average molecular weight of greater than or equal to about 50,000, for example about 50,000 to about 1,000,000, or about 50,000 to 500,000. Within the ranges, coating properties during formation of a thin film may be easily controlled.

The conjugated semiconductor polymer may be an alternate copolymer, a block copolymer, or a random copolymer.

The conjugated semiconductor polymer may include a structural unit represented by Chemical Formula 3.

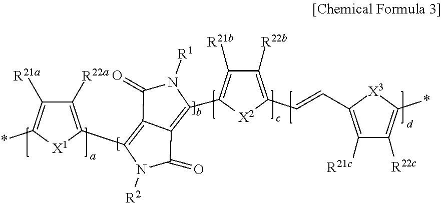

In Chemical Formula 3,

R¹ and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R¹ and R² is a substituted or unsubstituted C10 to C50 linear or branched alkyl group, for example a substituted or unsubstituted C15 to C50 linear or branched alkyl group or a substituted or unsubstituted C20 to C50 linear or branched alkyl group, a substituted or unsubstituted C10 to C50 linear or branched alkoxy group, for example a substituted or unsubstituted C15 to C50 linear or branched alkoxy group or a substituted or unsubstituted C20 to C50 linear or branched alkoxy group, a substituted or unsubstituted C10 to C50 linear or branched alkenyl group, for example a substituted or unsubstituted C15 to C50 linear or branched alkenyl group or a substituted or unsubstituted C20 to C50 linear or branched alkenyl group, or a substituted or unsubstituted C10 to C50 linear or branched alkynyl group, for example a substituted or unsubstituted C15 to C50 linear or branched alkynyl group or a substituted or unsubstituted C20 to C50 linear or branched alkynyl group,

X¹, X², and X³ are the same or different and are independently O, S, Se, or NR^{a} (wherein R^{a} is hydrogen or a C1 to C6 alkyl group),

R^{21a}, R^{22a}, R^{21b}, R^{22b}, R^{21c}, and R^{22c} are the same or different and are independently hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group,

* is a linking portion with an adjacent moiety.

a, c, and d are independently 0 to 10, and

b is 1 to 10.

In an embodiment, the conjugated semiconductor polymer may have a diketopyrrolopyrrole (DPP) structural unit. The structural unit may provide high charge mobility when the conjugated polymer is manufactured into a thin film.

The conjugated semiconductor polymers are entangled one another and form a mesh-structured network, and in the network, the plasticizer compound having the linear or branched aliphatic hydrocarbon group is dispersed. The plasticizer compound having the linear or branched aliphatic hydrocarbon group has a larger volume and decreases inter-chain coupling of the conjugated semiconductor polymer and thus a mechanical modulus of the conjugated semiconductor polymer but increase mechanical ductility and decrease crystallinity and accordingly, may provide an organic semiconductor thin film having higher stretchability and self-healing properties. In addition, the plasticizer compound having the linear or branched aliphatic hydrocarbon group does not deteriorate charge carrier mobility of the conjugated semiconductor polymer and thus has little to no influence on electrical characteristics of the conjugated semiconductor polymer.

The linear or branched aliphatic hydrocarbon group of the plasticizer compound having the linear or branched aliphatic hydrocarbon group may be a substituted or unsubstituted C4 to C50 linear or branched alkyl group, for example a substituted or unsubstituted C6 to C50 linear or branched alkyl group, a substituted or unsubstituted C4 to C50 linear or branched alkoxy group, for example a substituted or unsubstituted C6 to C50 linear or branched alkoxy group, a substituted or unsubstituted C4 to C50 linear or branched alkenyl group, for example a substituted or unsubstituted C4 to C50 linear or branched alkenyl group, or a substituted or unsubstituted C6 to C50 linear or branched alkynyl group, for example a substituted or unsubstituted C6 to C50 linear or branched alkynyl group. For the linear or branched aliphatic hydrocarbon group of the plasticizer compound, “substituted” refers to replacement of hydrogen of a functional group by a functional group selected from a halogen atom, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C20 alkyl group, a C1 to C20 alkoxy group, a C1 to C20 haloalkyl group, a C2 to C20 alkenyl group, a C2 to C20 alkynyl group, and a C1 to C20 heteroalkyl group. In addition, the methylene group of the alkyl group, the alkoxy group, the alkenyl group, or the alkynyl group may be replaced by —C(═O)O—, —OC(═O)—, —O—, and a combination thereof.

The plasticizer compound having the linear or branched aliphatic hydrocarbon group is a compound having a linear or branched aliphatic hydrocarbon group at an aromatic chain or an aliphatic chain and thus has a low glass transition temperature and thus secure stretchability compared with a plasticizer compound having an alicyclic chain. The plasticizer compound having an alicyclic chain is crystallized at room temperature and thus is rigid and may not secure stretchability.

The plasticizer compound having the linear or branched aliphatic hydrocarbon group may be an aromatic or aliphatic compound including at least two ester groups.

The aromatic or aliphatic compound may be a phthalate-based compound, a trimellitate-based compound, an aliphatic ester-based compound, or a combination thereof.

Examples of the phthalate-based compound may be an alkyl phthalate-based compound such as dibutyl phthalate (DBP), dioctyl phthalate (DOP), diisononyl phthalate (DINP), di-isodecyl phthalate (DIDP), dihexyl phthalate (DEHP), diheptyl phthalate, diisodecyl phthalate, diundecyl phthalate, di-isooctylphthalate (DIOP), di-capryl phthalate (DCP), di-n-octylphthalate (DOP), di-2-ethylhexyl isophthalate (DOIP), di-2-ethylhexyl terephthalate (DOTP), di-isononyl phthalate (DIHP), di-n-C6,C8,C10 phthalate (NHDP), di-linear-C7,C9,C11 phthalate (NHUP), di-tridecyl phthalate (DTDP), di-iso-C11,C12,C13 phthalate (UDP), or di-linear-C11 phthalate (DUP), examples of the trimellitate-based compound may be an alkyl trimellitate-based compound such as trioctyl trimellitate (TOTM), tri-i-tridecyl trimellitate, or triisononyltrimellitate (TINTM), examples of the aliphatic ester-based compound may be an alkyl maleate-based compound such as dioctyl maleate; an alkyl adipate compound such as dibutyl adipate (DBA) or dioctyl adipate; an alkyl sebacate compound such as dioctyl sebacate (DOS); or an alkyl azelate compound such as dioctyl azelate (DOZ). The alkyl may be a C4 to C50 linear or branched alkyl, for example a C4 to C50 linear or branched alkyl.

The plasticizer compound having the linear or branched aliphatic hydrocarbon group may have a molecular weight of greater than or equal to about 250 g/mol, greater than or equal to about 260 g/mol, greater than or equal to about 280 g/mol, greater than or equal to about 300 g/mol, or greater than or equal to about 340 g/mol and less than or equal to about 800 g/mol. The plasticizer compound having a molecular weight within the ranges is inserted into the network of the conjugated semiconductor polymer and thus may effectively decrease an inter-chain coupling among the polymers.

The plasticizer compound having the linear or branched aliphatic hydrocarbon group may have a boiling point of greater than or equal to about 350° C., for example greater than or equal to about 390° C. and less than or equal to about 800° C.

The plasticizer compound having the linear or branched aliphatic hydrocarbon group may be included in an amount of greater than or equal to about 0.1 parts by weight and less than or equal to about 2.0 parts by weight based on 1 part by weight of the conjugated semiconductor polymer. In an embodiment, the plasticizer compound having the linear or branched aliphatic hydrocarbon group may be included in an amount of greater than or equal to about 0.2 parts by weight, greater than or equal to about 0.3 parts by weight, greater than or equal to about 0.4 parts by weight, or greater than or equal to about 0.5 parts by weight based on 1 part by weight of the conjugated semiconductor polymer. In an embodiment, the plasticizer compound having the linear or branched aliphatic hydrocarbon group may be included in an amount of less than or equal to 1.9 parts by weight, less than or equal to about 1.8 parts by weight, less than or equal to about 1.7 parts by weight, less than or equal to about 1.6 parts by weight, or less than or equal to about 1.5 parts by weight based on 1 part by weight of the conjugated semiconductor polymer. When the plasticizer compound is included within the range, high stretchability and self-healing properties may be applied to an organic semiconductor thin film by effectively decreasing inter-chain coupling of the conjugated semiconductor polymer.

The organic semiconductor thin film according to an embodiment shows no micro-sized crack found by an optical microscope when 100% elongated.

The organic semiconductor thin film may be formed by dissolving the conjugated semiconductor polymer and the plasticizer compound having the linear or branched aliphatic hydrocarbon group in an organic solvent to prepare a composition, coating the composition on a substrate, and removing the solvent.

The conjugated semiconductor polymer and the plasticizer compound having the linear or branched aliphatic hydrocarbon group are the same as described above.

The solvent is not particularly limited as long as it may uniformly dissolve the conjugated semiconductor polymer and the plasticizer compound having the linear or branched aliphatic hydrocarbon group. For example, the solvent may include chloroform, chlorobenzene, toluene, dimethylformaldehyde, tetrahydrofuran, dimethylsulfoxide, xylene, tetralin, or a combination thereof, but is not limited thereto.

The substrate may be for example a glass substrate or a polymer substrate, and the polymer substrate may be for example made of polyethylene terephthalate, polyethylene naphthalate, polycarbonate, polyacrylate, polyimide, or a combination thereof, but is not limited thereto.

The composition may be coated on the substrate using for example a spin coating, a slit coating, a bar coating, a dip coating, a spray coating, an inkjet printing, and the like, but is not limited thereto. In an embodiment, the composition may be for example coated using for example spin coating.

The organic semiconductor thin film may be transferred on an elastic substrate (e.g. styrene ethylene/butylene styrene (SEBS)), for example, by contacting the elastic substrate with the organic semiconductor thin film and then removing the substrate therefrom.

The process of manufacturing the organic semiconductor thin film may further include a process of removing the plasticizer compound having the linear or branched aliphatic hydrocarbon group. The plasticizer compound may be removed by using an alcohol solvent such as methanol and the like.

The organic semiconductor thin film may be applied to various electronic devices, for example a thin film transistor, a solar cell, an organic light emitting diode (OLED) display, and an organic sensor. In addition, the electronic device may be a stretchable organic light emitting diode (OLED) display, a stretchable human information sensor such as a stretchable human motion sensor or a stretchable electrocardiogram (ECG) sensor, a stretchable artificial muscle, or a stretchable actuator.

The thin film transistor may include a gate electrode,

an insulation layer disposed on the gate electrode,

a semiconductor layer disposed on the insulation layer and including the organic semiconductor thin film, and

a source electrode and a drain electrode electrically connected to the semiconductor layer.

Hereinafter, an example embodiment of a thin film transistor including organic semiconductor thin film is described with reference to the drawings.

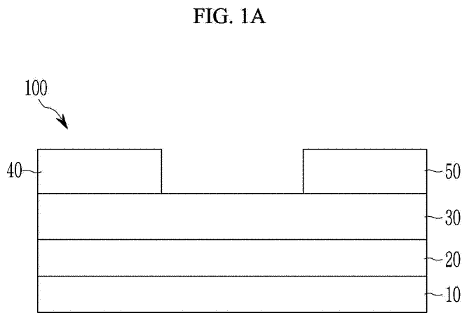

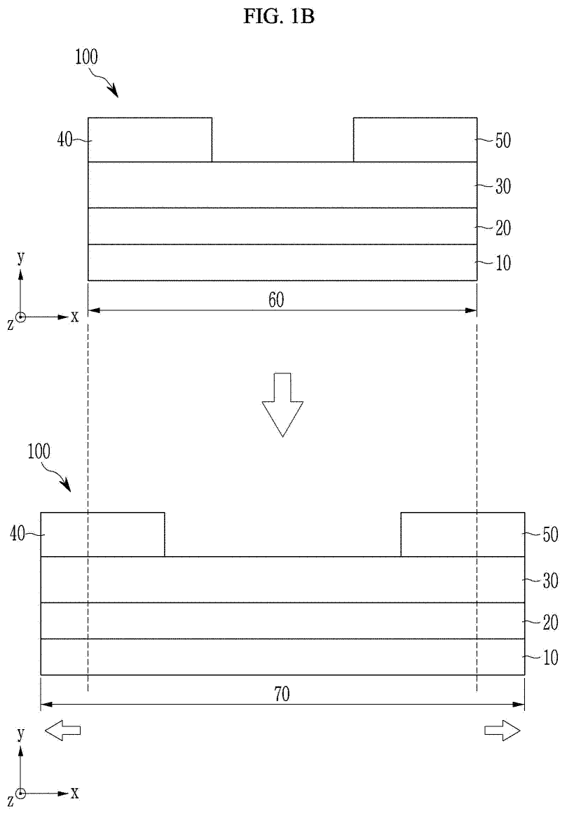

FIG. 1A is a cross-sectional view of a thin film transistor according to example embodiments and FIG. 1B is a schematic cross-sectional view showing a thin film transistor according to example embodiments without strain (upper) and with strain (bottom).

Referring to FIG. 1A, the thin film transistor 100 includes a substrate 10, an insulation layer 20, a semiconductor layer 30, a source electrode 40, and a drain electrode 50.

The substrate 10 may include a gate electrode or may function as a gate electrode. The substrate 10 may be made of transparent glass, silicon, or plastic. The gate electrode may be doped at a high concentration in a silicon substrate or may be a conductive layer (e.g., a metal layer made of gold (Au), copper (Cu), nickel (Ni), aluminum (Al), molybdenum (Mo), chromium (Cr), tantalum (Ta), titanium (Ti), an alloy thereof; a conductive carbon-based material made of a CNT layer, conductive polymers, or a graphene layer; a conductive ink; or a combination thereof) disposed on an insulating substrate (e.g., a polymer substrate made of a rubber such as PDMS or SEBS, a polyester, a polycarbonate, a polyimide, and the like).

An insulation layer 20 is disposed on the substrate 10. The insulation layer 20 separates the gate electrode and the source electrode 40, the drain electrode 50, and the semiconductor layer 30. The insulation layer 20 may be an inorganic material thin film or an organic polymer film. Examples of an inorganic material may include silicon oxide, silicon nitride, aluminum oxide, barium titanite, and the like, but are not limited thereto. Examples of an organic polymer may include a polyester, a polycarbonate, a poly(vinyl phenol), a polyimide, a polystyrene, a poly(methacrylate), a poly(acrylate), an epoxy resin, and the like, but are not limited thereto. In addition, when the organic semiconductor thin film is transferred on an elastic substrate, the elastic substrate may function as an insulation layer.

A thickness of the insulation layer 20 may be changed depending on a dielectric constant of an insulating material but is not limited thereto. For example, the insulation layer 20 may have a thickness of greater than or equal to about 10 nm, for example, greater than or equal to about 50 nm, or greater than or equal to about 100 nm, but is not limited thereto. The insulation layer 20 may have a thickness of less than or equal to about 2000 nm, for example, less than or equal to about 500 nm, but is not limited thereto. The insulation layer 20 may have conductivity of less than or equal to about 10⁻¹²S/cm but is not limited thereto.

The semiconductor layer 30 is disposed on the insulation layer 20 and the semiconductor layer 30 includes the organic semiconductor thin film.

The source electrode 40 and the drain electrode 50 are disposed on the semiconductor layer 30.

The materials of the source electrode 40 and the drain electrode 50 may include a metal such as gold (Au), copper (Cu), nickel (Ni), aluminum (Al), molybdenum (Mo), chromium (Cr), tantalum (Ta), titanium (Ti), and an alloy thereof; a conductive carbon-based material made of a CNT layer, conductive polymers, or a graphene layer; a conductive ink; or a combination thereof, but are not limited thereto. Thicknesses of the source electrode 40 and the drain electrode 50 may be selected appropriately.

Referring to FIG. 1B, the thin film transistor 100 may be elastically deformed. The unstrained profile 60 of the thin film transistor should have different measurements in the x, y, and z axes from the strained profile 70, but should have the same cross-sectional area as the strained profile 70. The change from the unstrained profile and the strained profile may also change the thin film transistors current over time characteristics, allowing the thin film transistor to act as a stress sensor.

Although a thin film transistor having a top contact/bottom gate structure is provided as an example, the structure of the thin film transistor is not limited thereto, and it include other thin film transistors such as a bottom contact/top gate structure, a bottom contact/bottom gate structure, and a top contact/top gate structure in the same manner.

The thin film transistor may be applied as a switch element or a driving device of various electronic devices. In an embodiment, the electronic device may be a stretchable electronic device. For example, the electronic device may be a stretchable organic light emitting diode (OLED) display, a stretchable human information sensor such as a stretchable human motion sensor or a stretchable electrocardiogram (ECG) sensor, a stretchable artificial muscle, or a stretchable actuator.

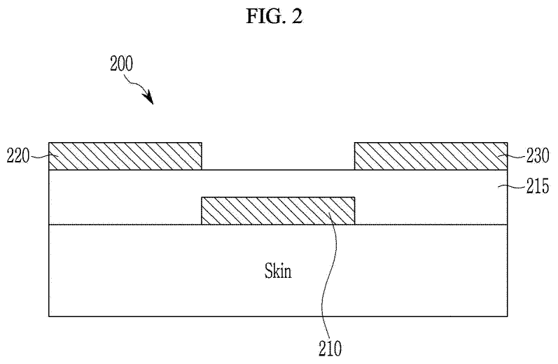

For example, the stretchable electrocardiogram (ECG) sensor is described with reference to FIG. 2. FIG. 2 is a schematic cross-sectional view showing the structure of an electrocardiogram (ECG) sensor. Referring to FIG. 2, a stretchable electrocardiogram (ECG) sensor 200 includes a first electrode 210, an insulation layer 215 on the first electrode 210, and a second electrode 220 and a third electrode 230. The first electrode 210, second electrode 220, and third electrode 230 may include a conductor and a matrix polymer. The conductor may include carbon nanotubes (CNT), carbon nanofibrils (CNF), carbon nanowalls (CNW), graphenes (or other two-dimensional (2D) materials), carbon nanotubes (CNT) doped with nanometals, carbon nanofibrils doped with nanometals, carbon nanowalls doped with nanometals, graphenes (or other two-dimensional (2D) materials) doped with nanometals, nanometals, conductive metal oxides, or a combination thereof. The matrix polymer may include a network of conjugated semiconductor polymers including at least one conjugated structural unit and a plasticizer compound dispersed in the polymer network and having a linear or branched aliphatic hydrocarbon group, wherein the conjugated structural unit includes at least one long-chain linear or branched aliphatic hydrocarbon group as a side chain.

Hereinafter, the embodiments are illustrated in more detail with reference to examples. However, these examples are example embodiments, and the scope of the claims is not limited thereto.

### EXAMPLES

### Examples 1 to 3: Manufacture of Organic Semiconductor Thin Film

A conjugated semiconductor polymer represented by Chemical Formula 1A and dioctyl phthalate as a plasticizer compound are mixed in each weight ratio of 1:0.25, 1:0.5, and 1:1 and then, dissolved in 0.02 ml of chlorobenzene to prepare compositions (2.5 mg/ml). Each composition is spin-coated on a SEBS elastic substrate for 1 minute and annealed under a nitrogen atmosphere at 150° C. for 1 hour to manufacture each organic semiconductor thin film according to Examples 1 to 3.

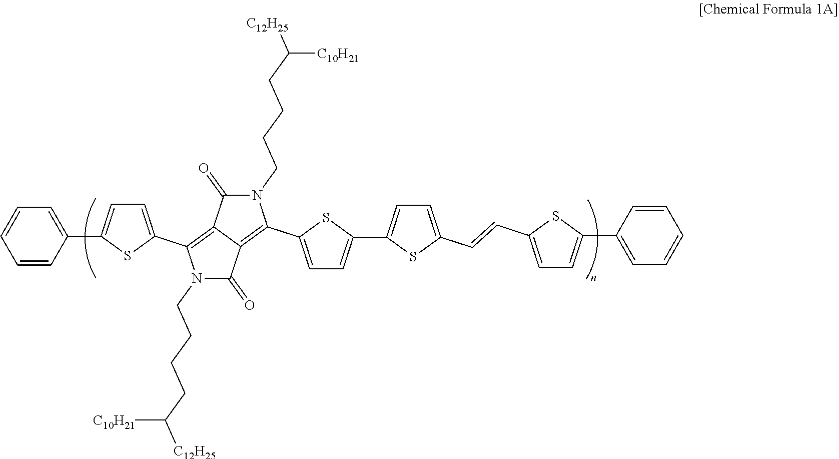

In Chemical Formula 1A, n is 50.

### Examples 4 to 6: Manufacture of Organic Semiconductor Thin Film

The organic semiconductor thin films according to Examples 1 to 3 are treated with methanol to remove the plasticizer compound to respectively manufacture the organic semiconductor thin films according to Examples 4 to 6.

### Example 1 (50%) to Example 6 (50%) and Example 1 (100%) to Example 6 (100%): Manufacture of Organic Semiconductor Thin Film

The organic semiconductor thin films according to Examples 1 to 6 are respectively 50% elongated to manufacture each organic semiconductor thin film according to Example 1 (50%) to Example 6 (50%).

The organic semiconductor thin films according to Examples 1 to 6 are respectively 100% elongated to manufacture each organic semiconductor thin film according to Example 1 (100%) to Example 6 (100%).

### Comparative Example 1: Manufacture of Organic Semiconductor Thin Film

The conjugated semiconductor polymer represented by Chemical Formula 1A is dissolved in 0.02 ml of chlorobenzene without using the plasticizer compound to prepare a composition (2.5 mg/ml). The composition is spin-coated on a SEBS elastic substrate for 1 minute and annealed under a nitrogen atmosphere at 150° C. for 1 hour to prepare an organic semiconductor thin film.

### Comparative Example 1 (50%) and Comparative Example 1 (100%): Manufacture of Organic Semiconductor Thin Film

The organic semiconductor thin film according to Comparative Example 1 is 50% elongated to manufacture an organic semiconductor thin film according to Comparative Example 1 (50%).

The organic semiconductor thin film according to Comparative Example 1 is 100% elongated to manufacture an organic semiconductor thin film according to Comparative Example 1 (100%).

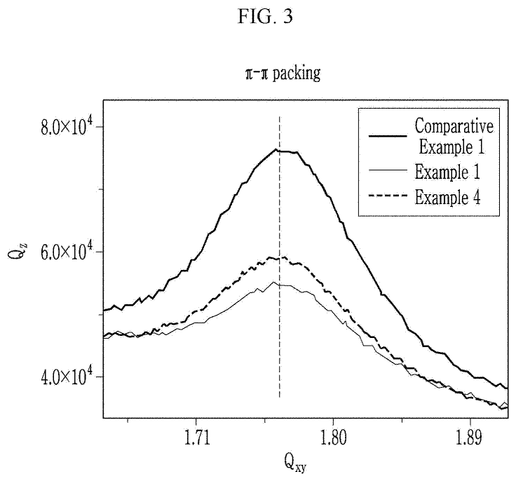

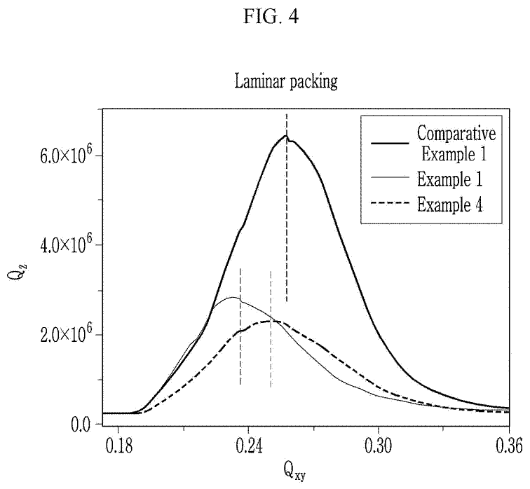

A π-π stacking distance and a laminar stacking distance of each organic semiconductor thin film according to Comparative Example 1 and Examples 1 and 4 are evaluated in an X-ray diffraction (XRD) method, and the results are respectively shown in FIGS. 3 and 4. FIG. 3 is a graph showing the π-π stacking distance of each organic semiconductor thin film according to Comparative Example 1 and Examples 1 and 4, and FIG. 4 is a graph showing the laminar stacking distance of each organic semiconductor thin film according to Comparative Example 1 and Examples 1 and 4.

Referring to FIGS. 3 and 4, the organic semiconductor thin films according to Examples 1 and 4 show almost no π-π stacking distance (Q_{xy}) change but an increased laminar stacking distance (Q_{xy}) compared with the organic semiconductor thin film according to Comparative Example 1. The organic semiconductor thin films according to Examples 1 and 4 show an increased laminar stacking distance (Q_{xy}) and thus are expected to show improved stretchability.

### Stretchability of Organic Semiconductor Thin Film

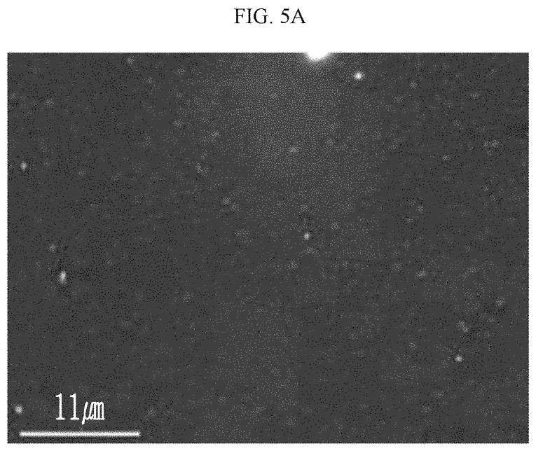

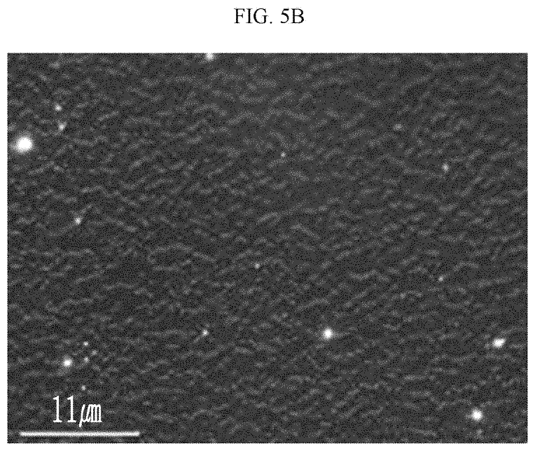

FIGS. 5A and 5B show each polarizing microscopic photograph of the organic semiconductor thin films according to Example 2 (100%) and Comparative Example 1 (100%). FIGS. 5A and 5B are polarizing microscopic photographs respectively showing the organic semiconductor thin films according to Example 2 (100%) and Comparative Example 1 (100%). Referring to FIGS. 5A and 5B, the organic semiconductor thin film according to Example 2 (100%) has no crack on the surface, but the organic semiconductor thin film according to Comparative Example 1 (100%) has a crack on the surface.

### Examples 7 to 9: Manufacture of Thin Film Transistor

The conjugated semiconductor polymer represented by Chemical Formula 1A is mixed with dioctyl phthalate as a plasticizer compound in each weight ratio of 1:0.25, 1:0.5, and 1:1 and dissolved in 0.02 ml of chlorobenzene to respectively prepare a composition (5 mg/ml).

The compositions are respectively spin-coated on an OTS (octadecyltrichlorosilane)-treated Si/SEBS substrate in a glove box and then annealed at 150° C. for 10 minutes to from each semiconductor layer. A source and drain electrode (Au, 40 nm) is thermally deposited thereon under 5.0×10⁶ torr to manufacture each thin film transistor.

### Examples 10 to 12: Manufacture of Thin Film Transistor

The conjugated semiconductor polymer represented by Chemical Formula 1A is mixed with dioctyl phthalate as a plasticizer compound in each weight ratio of 1:0.25, 1:0.5, and 1:1 and then, dissolved in 0.02 ml of chlorobenzene to respectively prepare compositions (2.5 mg/ml). The compositions are respectively spin-coated on an OTS (octadecyltrichlorosilane)-treated Si/SEBS substrate in a glove box and annealed at 150° C. for 10 minutes to respectively form a semiconductor layer, and then, each semiconductor layer is treated with methanol to remove the plasticizer compound. Subsequently, a source and drain electrodes (Au, 40 nm) are formed by thermal evaporation deposited thereon under 5.0×10⁶ torr to form each thin film transistor.

### Example 7 (100%) to Example 9 (100%): Manufacture of Thin Film Transistor

A conjugated semiconductor polymer having Chemical Formula 1A is mixed with dioctyl phthalate as a plasticizer compound in each weight ratio of 1:0.25, 1:0.5, and 1:1 and then, dissolved in 0.02 ml of chlorobenzene to prepare a composition (2.5 mg/ml). Each composition is spin-coated on an OTS (octadecyltrichlorosilane)-treated Si/SEBS substrate in a glove box and annealed at 150° C. for 10 minutes to respectively form a semiconductor layer. Subsequently, a source and drain electrode (Au, 40 nm) is thermally deposited thereon under 5.0×10⁶ torr to respectively manufacture a thin film transistor. Each thin film transistor is 100% elongated.

### Comparative Example 2: Manufacture of Thin Film Transistor

The conjugated semiconductor polymer represented by Chemical Formula 1A is dissolved in 0.02 ml of chlorobenzene without using a plasticizer compound to prepare a composition (2.5 mg/ml). The composition is spin-coated on an OTS (octadecyltrichlorosilane)-treated Si/SEBS substrate in a glove box and annealed at 150° C. for 10 minutes to form a semiconductor layer. Subsequently, a source and drain electrode (Au, 40 nm) is thermally deposited thereon under 5.0×10⁶ torr to form a thin film transistor.

Comparative Example 2 (100%): Manufacture of Thin Film Transistor

The thin film transistor according to Comparative Example 2 is 100% elongated.

### Electrical Characteristics of Thin Film Transistor

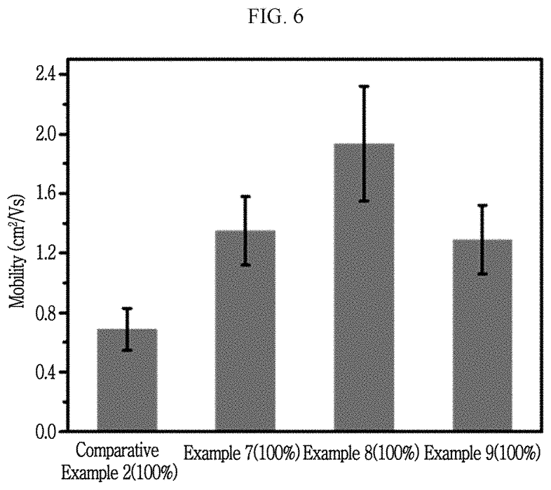

Mobility of the thin film transistors according to Examples and Comparative Examples is measured and shown in FIG. 6. The mobility is measured by using Semiconductor Characterization System (4200-SCS) made by Keithley Instruments Company. FIG. 6 is a graph showing mobility of the thin film transistors according to Comparative Example 2 (100%) and Examples 7 (100%), 8 (100%), and 9 (100%). Referring to FIG. 6, the thin film transistors according to Examples 7, 8, and 9 show improved mobility when compared to the thin film transistor according to Comparative Example 2.

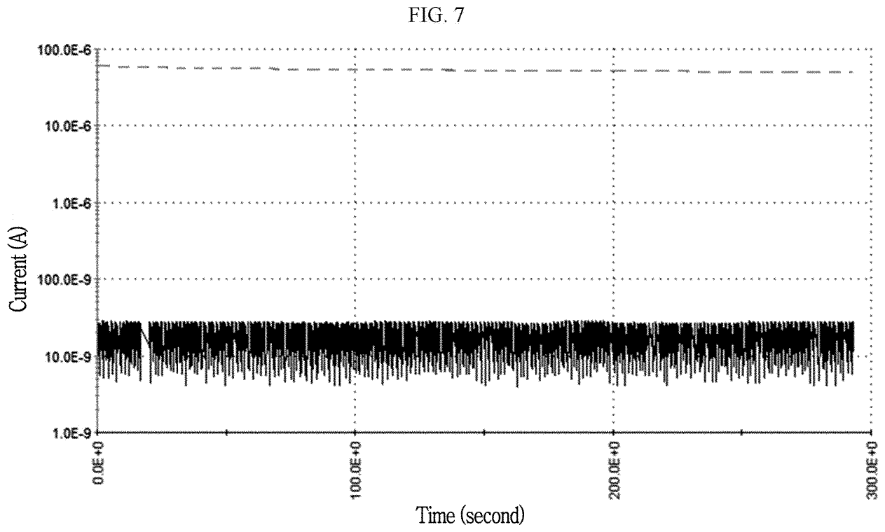

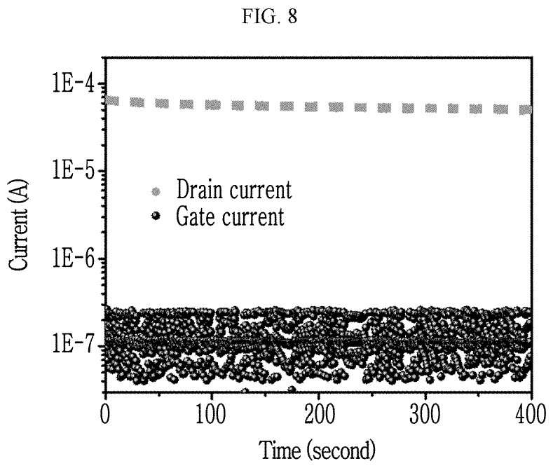

In order to examine electrical characteristics of the plasticizer compound, a current of each thin film transistor is measured under a bias-stress by operating it for 300 seconds under a turn-on state (VG=−100 V, VD=−100 V). The results of the thin film transistors according to Examples 8 and 11 are respectively shown in FIGS. 7 and 8. FIG. 7 is a graph showing a drain current (on current, gray line) and a gate leakage current (off current, black line) of the thin film transistor according to Example 8 under a turn-on state (VG=−100 V, VD=−100 V). Referring to FIG. 7, the drain current (on-current, gray line) is equally maintained with its initial value, and the gate leakage current (off current, black line) is also maintained with its initial value. FIG. 8 is a graph showing a drain current (on current, gray line) and a gate leakage current (off current, black line) of the thin film transistor according to Example 11 under a turn-on state (VG=−100 V, VD=−100 V). Referring to FIG. 8, the drain current (on-current, gray line) is equally maintained with its initial value, and the gate leakage current (off current, black line) is also maintained with its initial value. Accordingly, whether a thin film transistor includes a plasticizer compound, or the plasticizer compound is removed therefrom, the thin film transistor is stably operated.

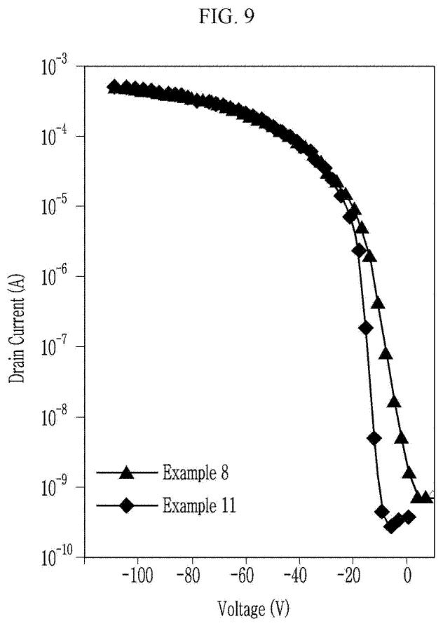

In addition, transfer characteristics of the thin film transistors are evaluated, and the results are shown in FIG. 9. FIG. 9 is a graph showing transfer (VGS sweep) characteristics of the thin film transistor of Example 8 and Example 11. Referring to FIG. 9, the transfer characteristics of the thin film transistor according to Example 8 and Example 11 are more stable.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A stretchable organic semiconductor thin film, comprising
a network of conjugated semiconductor polymers comprising at least one conjugated structural unit and a plasticizer compound dispersed in the polymer network and having a linear or branched aliphatic hydrocarbon group, wherein the conjugated structural unit comprises at least one long-chain linear or branched aliphatic hydrocarbon group at a side chain.

2. The stretchable organic semiconductor thin film of claim 1, wherein the long-chain linear or branched aliphatic hydrocarbon group is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group.

3. The stretchable organic semiconductor thin film of claim 1, wherein the conjugated structural unit comprises at least one of a moiety represented by Chemical Formulae 1-1 to 1-7: 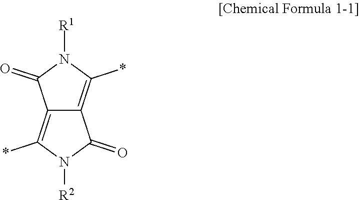
wherein, in Chemical Formula 1-1,
R¹ and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R¹ and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety, 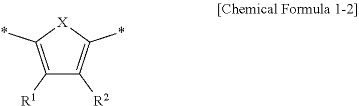
wherein, in Chemical Formula 1-2,
X is O, S, Se, or NR^{a}, wherein R^{a}, R¹, and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided at least one of R^{a}, R¹, and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety, 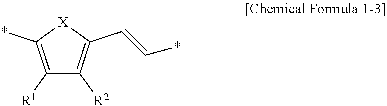
wherein, in Chemical Formula 1-3,
X is O, S, Se, or NR^{a}, wherein R^{a}, R¹, and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R^{a}, R¹, and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety, 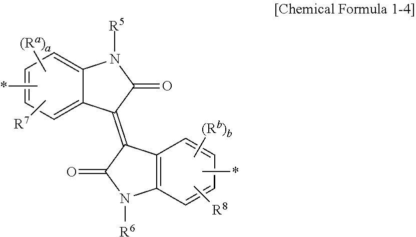
wherein, in Chemical Formula 1-4,
R⁵, R⁶, R⁷, and R⁸ are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R⁵, R⁶, R⁷, and R⁸ is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, R^{a} and R^{b} are a C1 to C6 alkyl group, a and b are each independently an integer of 0 to 2, and * is a linking portion with an adjacent moiety, 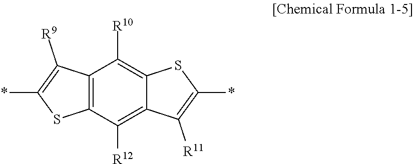
wherein, in Chemical Formula 1-5,
R⁹, R¹⁰, R¹¹, and R¹² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R⁹, R¹⁰, R¹¹ and R¹² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety, 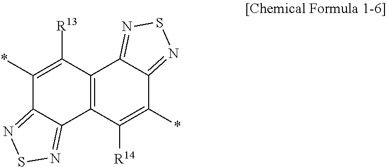
wherein, in Chemical Formula 1-6,
R¹³ and R¹⁴ are independently hydrogen, a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, provided that at least one of R¹³ and R¹⁴ is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety, 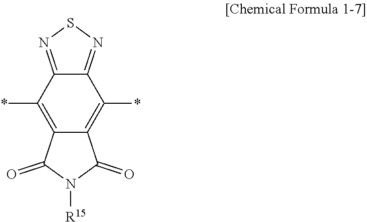
wherein, in Chemical Formula 1-7,
R¹⁵ is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group, and * is a linking portion with an adjacent moiety.

4. The stretchable organic semiconductor thin film of claim 1, wherein the conjugated structural unit comprises at least one of a moiety represented by Chemical Formulae 2-1 to 2-7: 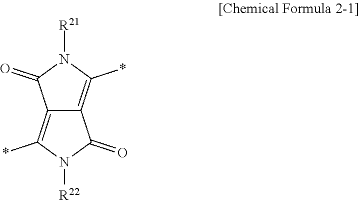
wherein, in Chemical Formula 2-1,
R²¹ and R²² are independently hydrogen, a halogen, a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety, 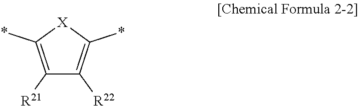
wherein, in Chemical Formula 2-2,
X is O, S, Se, or NR^{a} (wherein R^{a} is hydrogen or a C1 to C6 alkyl group), R²¹ and R²² are independently hydrogen, a halogen, a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety, 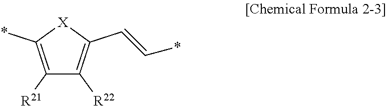
wherein, in Chemical Formula 2-3,
X is O, S, Se, or NR^{a} (wherein R^{a} is hydrogen or a C1 to C6 alkyl group), R²¹ and R²² is hydrogen, a halogen, a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group, and * is a linking portion with an adjacent moiety, 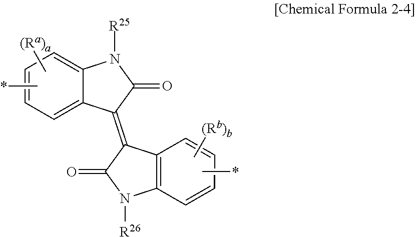
wherein, in Chemical Formula 2-4,
R²⁵ and R²⁶ are independently hydrogen, a halogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, R^{a} and R^{b} are a C1 to C6 alkyl group, a and b are independently an integer of 0 to 3, and * is a linking portion with an adjacent moiety, 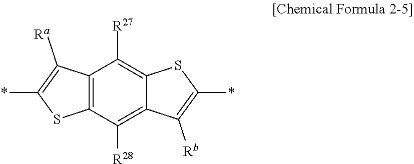
wherein, in Chemical Formula 2-5,
R²⁷ and R²⁸ are independently hydrogen, a halogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, R^{a} and R^{b} is hydrogen or a C1 to C6 alkyl group, and * is a linking portion with an adjacent moiety, 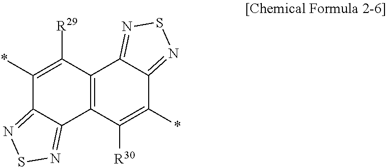
wherein, in Chemical Formula 2-6,
R²⁹ and R³⁹ are independently hydrogen, a halogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety, 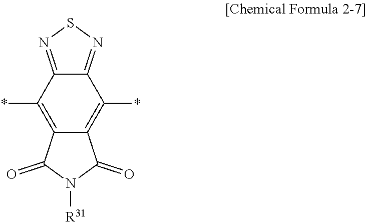
wherein, in Chemical Formula 2-7,
R³¹ is hydrogen, a halogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety, 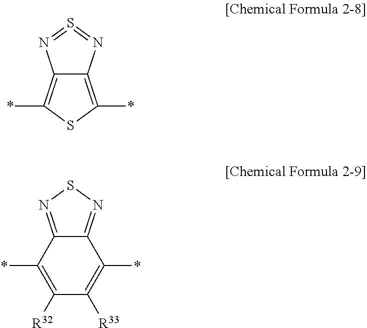
wherein, in Chemical Formula 2-9,
R³² and R³³ are independently hydrogen, a halogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, and * is a linking portion with an adjacent moiety, 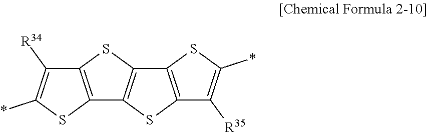
wherein, in Chemical Formula 2-10,
R³⁴ and R³⁵ are independently hydrogen, a halogen, a substituted or unsubstituted C1 to C40 alkyl group, a substituted or unsubstituted C2 to C40 alkenyl group, a substituted or unsubstituted C2 to C40 alkynyl group or a substituted or unsubstituted C6 to C30 aryl group, and * is a linking portion with an adjacent moiety.

5. The stretchable organic semiconductor thin film of claim 1, wherein the conjugated semiconductor polymer further comprises a substituted or unsubstituted phenylene, a substituted or unsubstituted thiazole, a substituted or unsubstituted pyridine, a substituted or unsubstituted bipyridine, a substituted or unsubstituted naphthalene, a substituted or unsubstituted anthracene, a substituted or unsubstituted phenanthroline, a substituted or unsubstituted naphthacene, a substituted or unsubstituted fluorene, a substituted or unsubstituted carbazole, a substituted or unsubstituted thienothiophene, a substituted or unsubstituted thieno benzothiophene, or a combination thereof.

6. The stretchable organic semiconductor thin film of claim 1, wherein the conjugated semiconductor polymers comprises a structural unit represented by Chemical Formula 3: 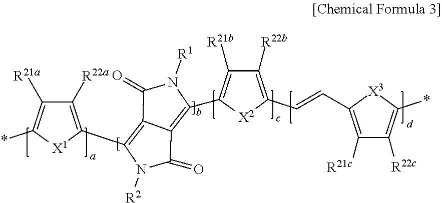
wherein, in Chemical Formula 3,
R¹ and R² are independently hydrogen, a substituted or unsubstituted linear or branched C1 to C50 alkyl group, a substituted or unsubstituted linear or branched C1 to C50 alkoxy group, a substituted or unsubstituted linear or branched C2 to C50 alkenyl group, a substituted or unsubstituted linear or branched C2 to C40 alkynyl group, or a substituted or unsubstituted C6 to C30 aryl group, provided that at least one of R¹ and R² is a substituted or unsubstituted C10 to C50 linear or branched alkyl group, a substituted or unsubstituted C10 to C50 linear or branched alkoxy group, a substituted or unsubstituted C10 to C50 linear or branched alkenyl group, or a substituted or unsubstituted C10 to C50 linear or branched alkynyl group,
X¹, X², and X³ are the same or different and are independently O, S, Se, or NR^{a} (wherein R^{a} is hydrogen or a C1 to C6 alkyl group),
R^{21a}, R^{22a}, R^{21b}, R^{22b}, R^{21c}, and R^{22c} are independently hydrogen, a halogen (F—, Cl—, Br—, or I—), a substituted or unsubstituted linear or branched C1 to C50 alkyl group, a substituted or unsubstituted C1 to C50 linear or branched alkoxy group, a substituted or unsubstituted linear or branched C2 to C50 alkenyl group, a substituted or unsubstituted linear or branched C2 to C50 alkynyl group, or a substituted or unsubstituted C6 to C30 aryl group,
* is a linking portion with an adjacent moiety,
a, c, and d are independently 0 to 10, and
b is 1 to 10.

7. The stretchable organic semiconductor thin film of claim 1, wherein the linear or branched aliphatic hydrocarbon group of the plasticizer compound having the linear or branched aliphatic hydrocarbon group is a substituted or unsubstituted C6 to C50 linear or branched alkyl group, a substituted or unsubstituted C6 to C50 linear or branched alkoxy group, a substituted or unsubstituted C6 to C50 linear or branched alkenyl group, or a substituted or unsubstituted C6 to C50 linear or branched alkynyl group.

8. The stretchable organic semiconductor thin film of claim 1, wherein the plasticizer compound having the linear or branched aliphatic hydrocarbon group is an aromatic or aliphatic compound having an ester group-containing linear or branched aliphatic hydrocarbon group.

9. The stretchable organic semiconductor thin film of claim 1, wherein the plasticizer compound having the linear or branched aliphatic hydrocarbon group is a phthalate-based compound, a trimellitate-based compound, an aliphatic ester-based compound, or a combination thereof.

10. The stretchable organic semiconductor thin film of claim 1, wherein the plasticizer compound having the linear or branched aliphatic hydrocarbon group is dibutyl phthalate (DBP), dioctyl phthalate (DOP), diisononyl phthalate (DINP), di-isodecyl phthalate (DIDP), dihexyl phthalate (DEHP), diheptyl phthalate, diisodecyl phthalate, diundecyl phthalate, di-isooctylphthalate (DIOP), di-capryl phthalate (DCP), di-n-octylphthalate (DOP), di-2-ethylhexyl isophthalate (DOIP), di-2-ethylhexyl terephthalate (DOTP), di-isononyl phthalate (DIHP), di-n-C6,C8,C10 phthalate (NHDP), di-linear-C7,C9,C11 phthalate (NHUP), di-tridecyl phthalate (DTDP), di-iso-C11,C12,C13 phthalate (UDP), di-linear-C11 phthalate (DUP), trioctyl trimellitate (TOTM), tri-i-tridecyl trimellitate, triisononyltrimellitate (TINTM), dioctyl maleate; dibutyl adipate (DBA), dioctyl adipate; dioctyl sebacate (DOS), (dioctyl azelate (DOZ), or a combination thereof.

11. The stretchable organic semiconductor thin film of claim 1, wherein the plasticizer compound having the linear or branched aliphatic hydrocarbon group has a molecular weight of greater than or equal to about 250 g/mol.

12. The stretchable organic semiconductor thin film of claim 1, wherein the plasticizer compound having the linear or branched aliphatic hydrocarbon group is included in an amount of about 0.1 to about 2 parts by weight based on 1 part by weight of the conjugated semiconductor polymers.

13. A thin film transistor comprising the stretchable organic semiconductor thin film of claim 1.

14. The thin film transistor of claim 13, wherein the thin film transistor comprises
a gate electrode,
an insulation layer disposed on the gate electrode,
a semiconductor layer including the stretchable organic semiconductor thin film of claim 1 and disposed on the insulation layer, and
a source electrode and a drain electrode electrically connected to the semiconductor layer.

15. An electronic device comprising the stretchable organic semiconductor thin film of claim 1.
